(19) United States
(12) Patent Application Publication
(10) Pub. No.: US 2015/0325636 A1
(43) Pub. Date: Nov. 12, 2015

(54) SEMICONDUCTOR DEVICE

(71) Applicant: Keisuke OTSUKA, (US)

(72) Inventor: Keisuke OTSUKA, Tokyo (JP)

(21) Appl. No.: 14/651,638

(22) PCT Filed: Nov. 29, 2013
(86) PCT No.: PCT/JP2013/082201

§ 371 Date: Jun. 11, 2015

(30) Foreign Application Priority Data
Dec. 12, 2012 (JP) 2012-271627

(51) Int. Cl. H01L 49/02

(52) U.S. Cl. CPC H01L 28/90

(57) ABSTRACT

The present invention is characterized by including a plurality of capacitors provided with: a plurality of lower electrodes which extend in a third direction orthogonal to a semiconductor substrate surface; a support film which is positioned flatly and in a manner so as to connect to the upper ends of the outer peripheral side surfaces of the lower electrodes, and which has openings that contain the plurality of lower electrodes; a capacitance insulating film which covers a surface of the lower electrodes; and an upper electrode which covers a surface of the capacitance insulating film. The present invention is also characterized in that the plurality of capacitors comprise: first capacitors provided with first lower electrodes, some of the upper ends of said lower electrodes being positioned in the openings in a planar view; and second capacitors provided with second lower electrodes, the upper ends of said lower electrodes not being positioned in the openings, and in that the first lower electrodes comprise: a first section not positioned in the opening; and a second section positioned in the opening. The upper ends of the first sections are positioned between the upper surface of the support film and the lower surface of the support film, and the upper ends of the second sections are positioned below the lower surface of the support film. The upper ends of the second lower electrodes are positioned between the upper surface of the support film and the lower surface of the support film.

### TECHNICAL FIELD

The present invention relates to a semiconductor device, and in particular relates to a semiconductor device having a construction in which a lower electrode of a capacitor is supported by a support film.

### BACKGROUND ART

FIG. 11A is a cross-sectional view including a plurality of capacitors of a semiconductor device forming a conventional DRAM (Dynamic Random Access Memory). In outline, the DRAM is formed from a memory cell region MCA and a peripheral circuit region PCA. Transistors comprising an embedded gate electrode 2, a cap insulating film 3, and an impurity-diffused layer 4, for example, are disposed on a semiconductor substrate 1 in the memory cell region MCA. Contact plugs 6 are disposed penetrating through a first interlayer insulating film 5, which is provided on the semiconductor substrate 1, and connecting to the impurity-diffused layers 4. A peripheral circuit 7 is disposed in the peripheral circuit region PCA. A stopper silicon nitride film 8 is disposed over the entire surface in such a way as to cover the peripheral circuit 7 and the contact plugs 6. A plurality of lower electrodes 21 connected to the upper surfaces of the contact plugs are provided penetrating through the stopper silicon nitride film 8, and a plurality of capacitors are formed by disposing a capacitative insulating film, which is not shown in the drawing, covering the surfaces of the lower electrodes, and an upper electrode 26 covering the surface of the capacitative insulating film. A via plug 28 is provided penetrating through a second interlayer insulating film 27 provided in such a way as to cover the capacitors, and the DRAM is formed, in outline, by the addition, for example, of an upper-layer wiring line 29 connected to the upper surface of the via plug 28.

In recent years, miniaturization of semiconductor devices has led to the mechanical strength of the lower electrodes being insufficient, and this frequently results in problems such as the collapse of the lower electrodes, or short-circuiting resulting from adjacent lower electrodes 21A and 21B moving together and coming into contact with one another, as illustrated in FIG. 11B. In order to avoid these problems, patent literature article 1 discloses a configuration in which a beam is provided in an arbitrary location in the Z-direction of the lower electrodes. Problems of capacitor short-circuiting attributable to collapse or moving together are thus avoided. However, in semiconductor devices in which miniaturization has progressed further, the diameter of cylinder holes used to form the lower electrodes is particularly small, and it is therefore difficult to form the lower electrodes with good coverage. Therefore if, as illustrated in FIG. 11C, lower electrodes 21c and 21d are formed in a cylinder hole 20 to a thickness T1 that is necessary and sufficient from the viewpoint of the capacitor characteristics, a widened portion 40 of the lower electrode having a film thickness T7 that is approximately twice as large forms at the opening portion, and the cylinder hole 20 becomes occluded at the stage at which the capacitative insulating film 25 has been formed. It is therefore not possible for the upper electrode 26 to be formed in the cylinder hole 20. In other words, the state is such that a capacitor is not formed on the lower electrode formed on the inner surface of the cylinder hole 20. Such a capacitor has a low capacitance and is therefore a defective capacitor, and problems thus arise inhibiting the operation of the semiconductor device.

Japanese Patent Kokai 2003-142605 (patent literature article 1) is an example of the related art.

### PATENT LITERATURE

Patent literature article 1: Japanese Patent Kokai 2003-142605

### SUMMARY OF THE INVENTION

### Problems to be Resolved by the Invention

The present invention provides a semiconductor device with which it is possible to avoid occlusion of the lower electrode and to form a normal capacitor, even if the diameter of the cylinder hole is small.

### Means of Overcoming the Problems

The semiconductor device according to one mode of embodiment of the present invention is characterized in that it comprises a plurality of capacitors provided with: a plurality of lower electrodes extending in a third direction perpendicular to a semiconductor substrate surface; a support film which is located in a plate-like manner, connected to an upper end portion of an outer peripheral side surface of each lower electrode, and which has an opening encompassing a plurality of the lower electrodes; a capacitative insulating film covering the surfaces of the lower electrodes; and an upper electrode covering the surface of the capacitative insulating film, wherein the plurality of capacitors include first capacitors provided with first lower electrodes in which a portion of the upper end of the lower electrode is located within the opening as seen in a plan view, and

second capacitors provided with second lower electrodes in which the upper end of the lower electrode is not located within the opening; and wherein the first lower electrodes are formed from a first part which is not located within the opening, and a second part which is located within the opening, and the upper end of the first part is located between the upper surface of the support film and the lower surface of the support film, the upper end of the second part is located lower than the lower surface of the support film, and the upper end of the second lower electrode is located between the upper surface of the support film and the lower surface of the support film.

### Advantages of the invention

According to the present invention, in the second lower electrodes in which the lower electrode is not located within the opening, the upper ends of said lower electrodes are located between the upper surface and the lower surface of the support film, with the widened portions of the lower electrode material film, located at the upper end portions of the side surfaces of the support film, having been removed, and therefore occlusion of the upper end portions of the cylinder holes can be avoided, and capacitors can be formed even if the diameter of the cylinder holes is small.

### BRIEF EXPLANATION OF THE DRAWINGS

FIG. 1A illustrates the configuration of the main parts of a semiconductor device according to the present invention, being a cross-sectional view through the line A-N illustrated in the plan view in FIG. 1B.

FIG. 1B is a plan view used to describe the layout.

FIG. 1C is an enlarged cross-sectional view of the region MC illustrated in FIG. 1A.

FIG. 1D is a cross-sectional view through the line B-B′ illustrated in the plan view in FIG. 1B.

FIG. 1E is an oblique view corresponding to the plan view in FIG. 1B.

FIG. 2A is a drawing used to describe a method of manufacturing the semiconductor device in the present invention illustrated in FIG. 1, being a cross-sectional view at a midway step, through the line A-A′ illustrated in FIG. 2B.

FIG. 2B is a plan view corresponding to the cross-sectional view in FIG. 2A.

FIG. 3A is a drawing used to describe the step following FIG. 2A, being a cross-sectional view through the line A-A′ in FIG. 2B.

FIG. 4A is a drawing used to describe the step following FIG. 3A, being a cross-sectional view through the line A-A′ in FIG. 2B.

FIG. 4C is an enlarged cross-sectional view of the region MC in FIG. 4A.

FIG. 5A is a drawing used to describe the step following FIG. 4A, being a cross-sectional view through the line A-A′ in FIG. 2B.

FIG. 5B is a plan view corresponding to the cross-sectional view in FIG. 5A.

FIG. 5C is an enlarged cross-sectional view of the region MC in FIG. 5A.

FIG. 6A is a drawing used to describe the step following FIG. 5A, being a cross-sectional view through the line A-A′ in FIG. 5B.

FIG. 6C is an enlarged cross-sectional view of the region MC in FIG. 6A.

FIG. 7A is a drawing used to describe the step following FIG. 6A, being a cross-sectional view through the line A-A′ in FIG. 7B.

FIG. 7B is a plan view corresponding to the cross-sectional view in FIG. 7A.

FIG. 7C is an enlarged cross-sectional view of the region MC in FIG. 7A.

FIG. 8A is a drawing used to describe the step following FIG. 7A, being a cross-sectional view through the line A-A′ in FIG. 7B.

FIG. 8C is an enlarged cross-sectional view of the region MC in FIG. 8A.

FIG. 9A is a drawing used to describe the step following FIG. 8A, being a cross-sectional view through the line A-A′ in FIG. 7B.

FIG. 9C is an enlarged cross-sectional view of the region MC in FIG. 9A.

FIG. 10 is a cross-sectional view used to describe a second mode of embodiment.

FIG. 11A is a cross-sectional view of a semiconductor device according to the prior art.

FIG. 11B is a cross-sectional view used to describe the problems in the prior art.

FIG. 11C is a cross-sectional view used to describe the problems in the prior art.

### MODES OF EMBODYING THE INVENTION

### First Mode of Embodiment

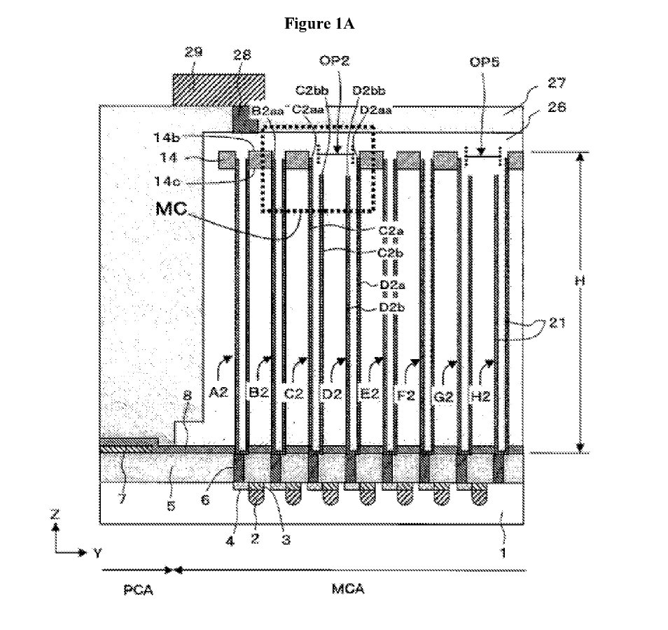

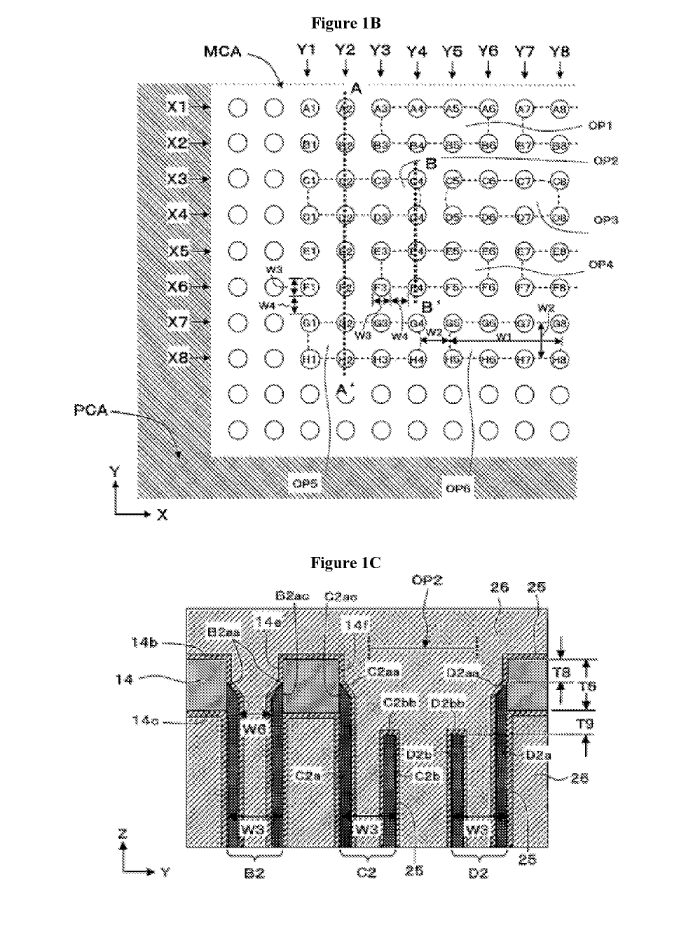

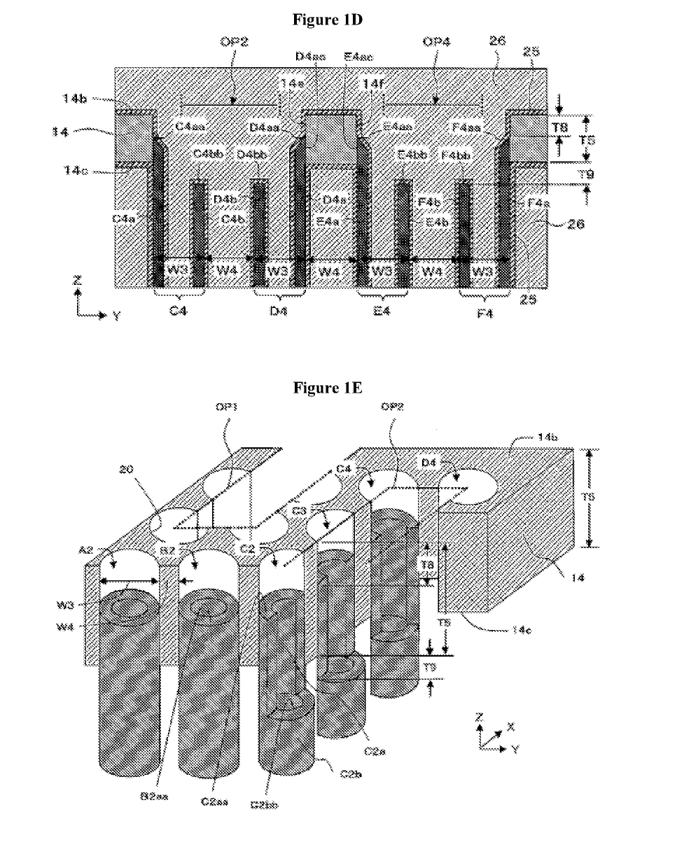

A first mode of embodiment of the present invention will now be described with reference to FIG. 1 to FIG. 9. In each drawing, Figure A is a cross-sectional view through A-N in the plan view illustrated in Figure B. Figure C is an enlarged cross-sectional view of the region MC illustrated in Figure A, Figure D is a cross-sectional view through the line B-B′ illustrated in the plan view in Figure D, and Figure E is an oblique view.

### Semiconductor Device

The configuration of the semiconductor device in this mode of embodiment will now be described with reference to FIG. 1. The semiconductor device in this mode of embodiment forms a DRAM.

FIG. 1A is a cross-sectional view through A-A′ in the plan view illustrated in FIG. 1B, discussed hereinafter. A DRAM comprises a memory cell region MCA in which a plurality of capacitors are formed, and a peripheral circuit region PCA. A plurality of embedded gate electrodes 2 and cap insulating films 3 covering the upper surfaces of the embedded gate electrodes 2 are disposed on the surface of a semiconductor substrate 1 located in the memory cell region MCA. Impurity-diffused layers 4 which form the source or drain of a transistor are disposed in the semiconductor substrate 1 adjacent to the cap insulating films 3. A plurality of contact plugs 6 connected to the impurity-diffused layers 4 are disposed penetrating through a first interlayer insulating film 5 disposed on the semiconductor substrate 1. Bit lines, which are not shown in the drawing, are formed in the first interlayer insulating film 5. It should be noted that the embedded gate electrodes 2 discussed hereinabove function as word lines. A peripheral circuit 7 is disposed on the first interlayer insulating film 5 in the peripheral circuit region PCA. A stopper silicon nitride film 8 is disposed in such a way as to cover the first interlayer insulating film 5, the contact plugs 6 and the peripheral circuit 7. Eight lower electrodes 21, A2 to H2, which penetrate through the stopper silicon nitride film 8 and are connected to the upper surfaces of the contact plugs 6, are disposed adjacent to one another in the Y-direction (first direction) which is parallel to the surface of the semiconductor substrate. It should be noted that in the following description, the reference codes A2 to H2 referring to the lower electrodes 21 sometimes refer to the corresponding capacitors. Further, the reference codes A2 to H2 sometimes refer to the lower electrodes.

The surfaces of the lower electrodes 21, A2 to H2, are covered by a capacitative insulating film, which is not shown in the drawings. The capacitative insulating film is further covered by an upper electrode 26. A via plug 28 connected to the upper electrode 26 is disposed penetrating through a second interlayer insulating film 27 covering the upper electrode 26, and an upper-layer wiring line 29 is provided connected to the upper surface of the via plug 28.

The plurality of capacitors disposed in the memory cell region MCA have a crown structure comprising the lower electrode 21, which has a ring shape as seen in a plan view. At least a portion of the upper end portions of the outer peripheral side surfaces of each of the lower electrodes 21 is connected to a support film 14. Openings OP2 and OP5 are disposed in the support film 14. The support film 14 is formed in the shape of a plate connected to all of the lower electrodes. The plurality of capacitors comprise first capacitors C2, D2, G2 and H2, in which a portion of the upper end of the lower electrode is located within an opening as seen in a plan view from the upper surface in the Z-direction (third direction), and second capacitors A2, B2, E2 and F2, in which the upper end of the lower electrode is not located within an opening. Focusing on the opening OP2, the first lower electrode C2 (21) which forms the first capacitor C2 is formed from a first part C2a, an upper end C2aa of which is not located within the opening OP2 as seen in a plan view, and a second part C2b, an upper end C2bb of which is located within the opening OP2. The upper end C2aa of the first part C2a is disposed between an upper surface 14b and a lower surface 14c of the support film 14. Further, the upper end C2bb of the second part C2b is disposed lower than the lower surface 14c of the support film 14 (toward the semiconductor substrate). The configuration is thus such that, in the first lower electrodes which form the first capacitors, the upper end portions of the outer peripheral side surfaces of the first parts, the upper ends of which are not located within the opening, are connected to the side surfaces of the support film 14, and the outer peripheral side surfaces of the second parts, the upper ends of which are located within the opening, are not connected to the support film 14. Another first capacitor D2 which faces the first capacitor C2 in the Y-direction is disposed in the opening OP2. The first lower electrode D2 (21) which forms the other first capacitor D2 is formed from a first part D2a, an upper end D2aa of which is not located within the opening OP2 as seen in a plan view, and a second part D2b, an upper end D2bb of which is located within the opening OP2. The upper end D2aa of the first part D2a is disposed between the upper surface 14b and the lower surface 14c of the support film 14. Further, the upper end D2bb of the second part D2b is disposed lower than the lower surface 14c of the support film 14 (toward the semiconductor substrate).

Therefore, within the one opening OP2 there are two first capacitors that face each other in the Y-direction, wherein the first lower electrodes C2 and D2 which form the first capacitors further comprise the first parts C2a and D2a, the upper ends C2aa and D2aa of which are not located within the opening OP2, and the second parts C2b and D2b, the upper ends C2bb and D2bb of which are located within the opening OP2, the configuration being such that the second part C2b, the upper end C2bb of which is located lower than the lower surface 14c of the support film 14, and the second part D2b, the upper end D2bb of which is similarly located lower than the lower surface 14c, face one other in closest proximity to one another.

Further, the semiconductor device in this mode of embodiment includes, as one unit configuration, the support film 14 which has a first side surface 14e and a second side surface 14f facing the first side surface 14e in the Y-direction; a second capacitor having a second lower electrode B2 which is in contact with the first side surface 14e of the support film 14 and an upper end B2aa of which is disposed between an upper surface 14b and a lower surface 14c of the support film 14; and a first capacitor having the first lower electrode C2 formed from a first part which is in contact with the second side surface 14f of the support film 14 and the upper end C2aa of which is disposed between the upper surface 14b and the lower surface 14c of the support film 14, and a second part which is not in contact with the support film 14 and the upper end C2bb of which is located lower than the lower surface 14c of the support film 14.

Meanwhile, focusing on the second capacitor B2 in which the upper end of the lower electrode is not located within the opening, the second lower electrode B2 which forms the second capacitor B2 has the upper end B2aa. The upper end B2aa is located between the upper surface 14b and the lower surface 14c of the support film 14. Further, the upper end portion of the outer peripheral side surface of the second lower electrode B2 is connected over its entire circumference to the side surface of the support film 14.

It should be noted that there is no particular restriction to the height H of each capacitor in FIG. 1A, in other words the height H from the upper surface of the contact plug 6 to the upper surface 14b of the support film 14, but the height can be selected within a range of between 1500 and 2000 nm.

Reference is now made to FIG. 1C. FIG. 1C is an enlarged cross-sectional view of the region MC indicated by the dotted line in FIG. 1A. The drawing illustrates the configuration of the upper portions of the first capacitors C2 and D2 and the second capacitor B2 described in FIG. 1A. As discussed hereinabove, the upper ends C2aa and D2aa of the first parts of the first lower electrodes which form the first capacitors are disposed between the upper surface 14b and the lower surface 14c of the support film 14. Further, an upper end portion C2ac of the outer peripheral side surface of the first part C2a, for example, is in contact with the side surface 14f of the support film. Further, the upper ends C2bb and D2bb of the second parts are located lower than the lower surface 14c. Further, the configuration is such that the upper end B2aa of the lower electrode forming the second capacitor is located between the upper surface 14b and the lower surface 14c of the support film 14. Further, the upper end portion of the outer peripheral side surface of the lower electrode B2 is in contact with the side surface of the support film 14. A capacitative insulating film 25 is disposed in such a way as to cover the entire upper surface 14b and lower surface 14c of the support film 14, the entire inner and outer surfaces of the lower electrodes, and the entire surface of the stopper silicon nitride film in FIG. 1A. Further, the upper electrode 26 is disposed in such a way as to cover the capacitative insulating film 25. As is clear from FIG. 1C, widened portions 40 which widen in the Y-direction illustrated in FIG. 1C are not present in the opening portions at the upper ends of each lower electrode, and therefore occlusion is prevented. Thus even when the capacitative insulating film 25 is disposed, the cylinder holes comprising the inner surfaces of the lower electrodes B2, C2 and D2 are adequately filled by the upper electrode 26. Capacitors are thus formed on the inner and outer surfaces of the lower electrodes, and the desired capacitance can therefore be obtained.

It should be noted that, as illustrated in FIG. 1C, the upper surfaces of the lower electrodes connected to the side surfaces of the support film 14 are formed with an inclination relative to a surface parallel to the surface of the semiconductor substrate 1. Therefore the description ‘upper surface of the lower electrode’ would be inaccurate when describing the location in the Z-direction, and therefore in the description hereinabove and the description hereinbelow, the description ‘upper end of the lower electrode’ is used.

As illustrated in FIG. 1C, the support film 14 has a thickness T5 in the Z-direction. In this mode of embodiment, the thickness T5 is in a range of between 100 and 150 nm. The difference T8 between the upper ends C2aa and D2aa of the first parts C2a and D2a of the first lower electrodes C2 and D2, and the upper surface 14b of the support film 14, is in a range of between 20 and 50% of the thickness T5 of the support film 14. In other words, the upper ends C2aa and D2aa are disposed in a location that is lower than the upper surface 14b by the difference T8. The abovementioned range is more preferably a range of between 30 and 40%. If this value is less than 20% then the widened portion discussed hereinabove remains, and the effect of avoiding occlusions is weakened, and if it exceeds 50% then there is an increased risk that the lower electrodes themselves will not be connected to the support film 14. The upper end B2aa of the second lower electrode B2 has the same configuration.

Meanwhile, the difference T9 between the upper ends C2bb and D2bb of the second parts C2b and D2b of the first lower electrodes, and the lower surface 14c of the support film 14, is in a range of between 15 and 70% of the thickness T5 of the support film 14. In other words, the upper ends C2bb and D2bb are disposed in a location that is lower than the lower surface 14c by the difference T9. The locations of the upper ends C2bb and D2bb of the second parts C2b and D2b are unambiguously defined by controlling the locations of the upper ends C2aa and D2aa of the first parts.

Reference is now made to the plan view in FIG. 1B. For convenience of explanation, a portion of the memory cell region MCA and the peripheral circuit region PCA have been extracted and illustrated in FIG. 1B. FIG. 1B is a plan view of a state in which the upper surface 14b of the support film 14 is exposed. A plurality of lower electrodes (capacitors) corresponding to capacitors are disposed in the memory cell region MCA, aligned in the Y-direction and in the X-direction (second direction) which is perpendicular to the Y-direction. For example, in the X1 row, lower electrodes A1 to A8 are disposed, and in the Y2 column, lower electrodes A2 to H8 are disposed in FIG. 1A. FIG. 1B illustrates the arrangement layout of openings OP1, OP2, OP3, OP4, OP5 and OP6. When seen in a plan view, the openings are each formed as a rectangle having long edges in the X-direction parallel to the surface of the semiconductor substrate, and short edges in the Y-direction, perpendicular to the X-direction. Focusing on the Y2 column corresponding to the cross-sectional view in FIG. 1A, the lower electrodes A2, B2, E2 and F2, the upper ends of which are not exposed within an opening, and the lower electrodes C2, D2, G2 and H2, portions of the upper ends of which are exposed in an opening, are disposed in a regular manner in the Y-direction. Focusing, for example, on the opening OP2, four lower electrodes adjacent in the X-direction, from the plurality of lower electrodes adjacent to one another with an equal spacing in straight lines in the Y-direction and the X-direction, serve as a unit lower electrode group, and the opening OP2 pattern is configured in such a way as to expose collectively portions of the respective upper ends of two adjacent unit lower electrode groups aligned in the Y-direction. In other words, the configuration is such that portions of the respective upper ends of a first unit lower electrode group comprising the four lower electrodes C1, C2, C3 and C4 that are adjacent in the X-direction, and portions of the respective upper ends of a second unit lower electrode group comprising the four lower electrodes D1, D2, D3 and D4 that are adjacent and are aligned in the Y-direction are exposed collectively.

Thus the configuration is such that the opening contains four lower electrodes which are located on the long edges of the opening, are divided into two in the diametrical direction, and in which a portion (equivalent to a half) of the upper ends of the lower electrodes, which are ring-shaped as seen in a plan view, are exposed, and four lower electrodes which are located at the corners of the opening, and in which only a portion (equivalent to a quarter) of the upper ends of the lower electrodes, which are ring-shaped as seen in a plan view, are exposed. In other words, the configuration is such that, for C2, C3, D2 and D3, the equivalent of half of the upper ends of the ring-shaped lower electrodes is exposed in the opening OP2, and for C1, C4, D1 and D4, the equivalent of a quarter of the upper ends of the ring-shaped lower electrodes is exposed in the opening OP2.

If the diameter of the outer circumference of each lower electrode is W3 and the gap between two lower electrodes that are adjacent and in closest proximity to one another is W4, then the arrangement pitch of the lower electrodes is defined as W3+W4, and the width of the openings in the X-direction, in other words the width W1 of the long edges, is configured to be three times the capacitor arrangement pitch. Further, the width in the Y-direction, in other words the width W2 of the short edges, is configured to be W3+W4, in other words the capacitor arrangement pitch. The gap between openings adjacent to one another in the X-direction is also configured to be the capacitor arrangement pitch W2. The gap between openings disposed adjacent to one another in the Y-direction is also configured to be the capacitor arrangement pitch W2. However, the plurality of openings adjacent to one another in the Y-direction are not all disposed in a straight line, but are staggered, each offset by ⅔ of W1 in the X-direction (twice the capacitor arrangement pitch). For example, the opening OP4 that is adjacent to the opening OP5 in the Y-direction is disposed in a location that is offset by 2×W2 in the X-direction. Further, the opening OP3 that is adjacent in the Y-direction is disposed in a location that is further offset by 2×W2 in the X-direction. From an alternative viewpoint, the openings are disposed in such a way that alternate openings arranged in the Y-direction are aligned in a straight line. The centerline, in the X-direction, of each opening does not intersect the openings that are in closest adjacent proximity in the Y-direction, the configuration being such that said centerline coincides with the centerlines, in the X-direction, of alternate openings arranged in the Y-direction. As described hereinabove, the beam 14 in this mode of embodiment is not divided in the shape of lines, but is configured as a continuous surface-like beam connected to all the lower electrodes disposed within one memory cell region.

Reference is now made to FIG. 1D. FIG. 1D is a cross-sectional view through the line B-W illustrated in the plan view in FIG. 1B. A first opening OP2 and a second opening OP4 are adjacent to one another in the first direction, sandwiching the support film 14. The support film 14 has a first side surface 14e located on the first opening OP2 side, and a second side surface 14f located on the second opening OP4 side, facing the first side surface 14e in the Y-direction. An upper end portion D4ac of the outer peripheral side surface of a first part D4a of a first lower electrode D4 which forms a first capacitor is connected to the first side surface 14e. Further, an upper end portion E4ac of the outer peripheral side surface of a first part E4a of a first lower electrode E4 which forms another first capacitor is connected to the second side surface 14f. One configuration of the semiconductor device, illustrated in FIG. 1D, is provided with: the support film 14 which has the first side surface 14e and the second side surface 14f facing the first side surface 14e in the Y-direction; the first capacitor having the first lower electrode D4 formed from a first part which is in contact with the first side surface 14e of the support film 14 and an upper end D4aa of which is disposed between the upper surface 14b and the lower surface 14c of the support film 14, and a second part which is not in contact with the support film 14 and an upper end D4bb of which is located lower than the lower surface 14c of the support film 14; and another first capacitor having the first lower electrode E4 formed from a first part which is in contact with the second side surface 14f of the support film 14 and an upper end E4aa of which is disposed between the upper surface 14b and the lower surface 14c of the support film 14, and a second part which is not in contact with the support film 14 and an upper end E4bb of which is located lower than the lower surface 14c of the support film 14; wherein the first capacitor D4, the other first capacitor E4 and the support film 14 located therebetween serve as a unit configuration, and the semiconductor device includes a configuration in which the unit configuration is disposed in a repeating manner in the Y-direction.

Reference is now made to the oblique view in FIG. 1E. FIG. 1E illustrates the positional relationship between the support film 14 illustrated in the plan view in FIG. 1B, the openings OP1 and OP2, the cylinder holes 20 and the lower electrodes disposed in the cylinder holes. The capacitative insulating film, the upper electrode and the like are omitted. The support film 14 comprising the upper surface 14b and the lower surface 14c, and having a thickness T5, is illustrated. A plurality of cylinder holes 20 aligned with an equal pitch spacing in the X-direction and the Y-direction are disposed in the beam 14. The second lower electrode B2 (A2), the upper end B2aa of which is located between the upper surface 14b and the lower surface 14c of the support film 14, and the upper end portion of the outer peripheral side surface of which is connected over its entire circumference to the side surface of the support film 14, is illustrated within a cylinder hole 20. Further, the first lower electrode C2 (C3, C4) comprising the first part C2a, the upper end C2aa of which is located between the upper surface 14b and the lower surface 14c of the support film 14, and the upper end portion of the outer peripheral side surface of which is connected to the side surface of the support film 14, and the second part C2b, the upper end C2bb of which is located lower than the lower surface 14c of the support film 14, and which is not connected to the support film 14, is illustrated within a cylinder hole 20. The first lower electrodes C2, C3 and C4 have a configuration in which a portion (C2bb) of the upper end of the lower electrode is located within the opening OP2, and the second lower electrodes A2 and B2 have a configuration in which the upper end of the lower electrode is not located within the opening. The upper ends B2aa and C2aa of the lower electrodes not located within the opening are located a thickness T8 below the upper surface 14b. Further, the drawing illustrates a configuration in which the upper ends C2bb of the lower electrodes located within the opening are located a thickness T9 below the lower surface 14c.

### Method of Manufacturing the Semiconductor Device

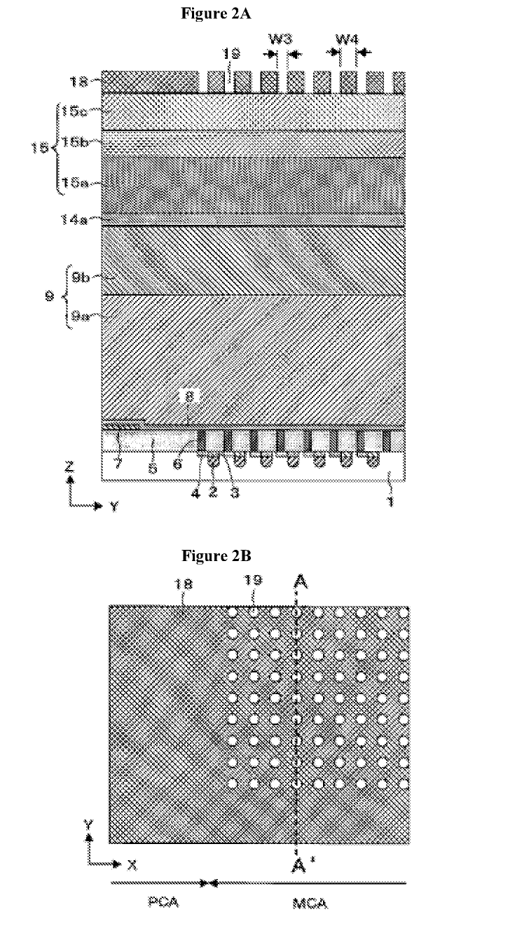

A method of manufacturing the semiconductor device according to the first mode of embodiment of the present invention will now be described with reference to FIG. 2 to FIG. 9. A DRAM comprises a memory cell region MCA in which a plurality of memory cells are disposed, and a peripheral circuit region PCA for driving the memory cells. FIG. 2 to FIG. 9 illustrate an area in the vicinity of a boundary part between the memory cell region MCA and the peripheral circuit region PCA in the course of manufacture of the DRAM. In each drawing, Figure A is a cross-sectional view through the line A-A′ in the plan view illustrated in Figure B, and Figure C is an enlarged cross-sectional view of the region MC illustrated in Figure A.

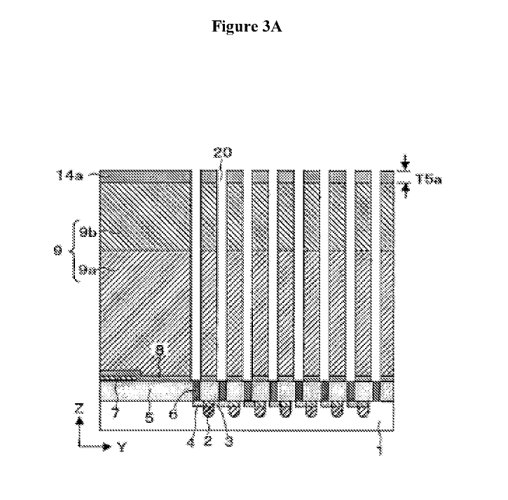

A cylinder-hole forming step is first carried out, as illustrated in FIG. 2A, FIG. 2B and FIG. 3A. To elaborate, as illustrated in FIG. 2A and FIG. 2B, embedded gate electrodes 2, cap insulating films 3, impurity-diffused layers 4 and the like, which form transistors, are formed in the memory cell region MCA of a semiconductor substrate 1. A first interlayer insulating film 5 is then formed on the semiconductor substrate 1, and contact plugs 6 connected to the impurity-diffused layers 4 are formed penetrating through the first interlayer insulating film 5. A peripheral circuit 7 and the like are formed in the peripheral circuit region PCA. Further, a stopper silicon nitride film 8 having a thickness of 50 nm, for example, and a sacrificial film 9 comprising a first sacrificial film 9a having a thickness of 900 nm, for example, and a second sacrificial film 9b having a thickness of 500 nm, for example, are formed. An insulating film 14a comprising silicon nitride having a thickness of 160 nm, for example, a hardmask film 15 and an organic masking film 18 are then formed successively in a laminated manner. The hardmask film 15 is formed from a laminated film comprising an amorphous silicon film 15a, a silicon dioxide film 15b and an amorphous carbon film 15c, for example.

The first sacrificial film 9a and the second sacrificial film 9b are formed from materials having different wet-etching rates. The first sacrificial film 9a is formed from a material having a relatively fast wet-etching rate, and the second sacrificial film 9b is formed from a material having a relatively slow wet-etching rate. The first sacrificial film 9a employs a silicon dioxide film (BPSG film) containing boron (B) and phosphorus (P), formed by CVD. The second sacrificial film 9b employs a non-doped silicon dioxide film.

After the organic masking film 18 on the uppermost layer has been formed, a plurality of cylinder hole patterns 19 are formed in the organic masking film 18 located in the memory cell region MCA, by means of a first lithography step. Here, the diameter W3 of the cylinder hole patterns 19 is 50 nm, for example. Further, the separation W4 is 30 nm, for example.

The semiconductor substrate 1 is a p-type single-crystal silicon substrate, for example. The semiconductor substrate 1 is isolated electrically into the memory cell region MCA and the peripheral circuit region PCA by means of an element isolation region, which is not shown in the drawings. The embedded gate electrodes 2 and the diffusion layers 4 formed in the memory cell region MCA form transistors. Further, the embedded gate electrodes 2 also function as word lines. The contact plugs 6 are connected to the lower electrodes of the capacitors in a later step. It should be noted that bit lines, which are not shown in the drawings, are formed within the first interlayer insulating film 5. The stopper silicon nitride film 8 is formed over the entire surface of the semiconductor substrate 1 by CVD, for example.

The insulating film 14a comprising a silicon nitride film is formed by CVD. The amorphous silicon film 15a is formed by CVD, for example, to a thickness of 1000 nm. The silicon dioxide film 15b is formed by CVD, for example, to a thickness of 50 nm. The amorphous carbon film 15c is formed by plasma CVD, for example, to a thickness of 500 nm.

The organic masking film 18 is formed from a laminated film comprising a photoresist and a silicon-containing antireflective film, for example. The openings which form the cylinder hole patterns 19 correspond to the locations in which the capacitors are to be formed. The diameter of the openings can be set to 40 to 80 nm, and the gap between openings that are in closest adjacent proximity can be set to 20 to 40 nm. With such a close-packed pattern in which multiple openings are disposed, the gap between adjacent openings, in other words the gap between the capacitors, is narrow, and it is thus difficult to dispose linear beams in a repeating manner in the X-direction and the Y-direction, as in methods of manufacturing related semiconductor devices. In this mode of embodiment, the structure is such that opening portions are formed in a support film, as discussed hereinbelow, and support is provided by a surface rather than by beams.

Next, as illustrated in FIG. 3A, the amorphous carbon film 15c is etched by anisotropic dry etching employing oxygen-containing plasma, using the organic masking film 18 as a mask. Further, the silicon dioxide film 15b is subjected to anisotropic dry etching using fluorine-containing plasma, to transfer the cylinder hole pattern 19 to the silicon dioxide film 15b. The organic masking film 18 and the amorphous carbon film 15c are then removed. The amorphous silicon film 15a is then subjected to anisotropic etching using the silicon dioxide film 15b as a mask, to transfer the cylinder hole pattern 19 to the amorphous silicon film 15a. The insulating film 14a, the second sacrificial film 9b, the first sacrificial film 9a and the stopper silicon nitride film 8 are then successively etched by anisotropic dry etching, using the silicon dioxide film 15b and the amorphous silicon film 15a as a mask, to form the cylinder holes 20. The silicon dioxide film 15b and the amorphous silicon film 15a are eliminated by means of this etching, exposing the upper surface of the insulating film 14a. The thickness T5a of the insulating film 14a at this stage is 140 nm, having been reduced by 20 nm. Further, the upper surfaces of the contact plugs 6 are exposed at the bottom surfaces of the cylinder holes 20.

Next, wet processing using a hydrofluoric acid (HF)-containing solution is performed as a wet-cleaning process to remove the dry etching residue, and as a pre-wash process prior to the following step of forming the lower electrode material film. The second sacrificial film 9b and the first sacrificial film 9a exposed in the cylinder holes 20 are etched by means of this wet processing, widening the cylinder holes 20. As discussed hereinabove, the wet etching rate of the first sacrificial film 9a is faster than that of the second sacrificial film 9b, and therefore the width of the cylinder holes 20 formed in the first sacrificial film 9a is greater.

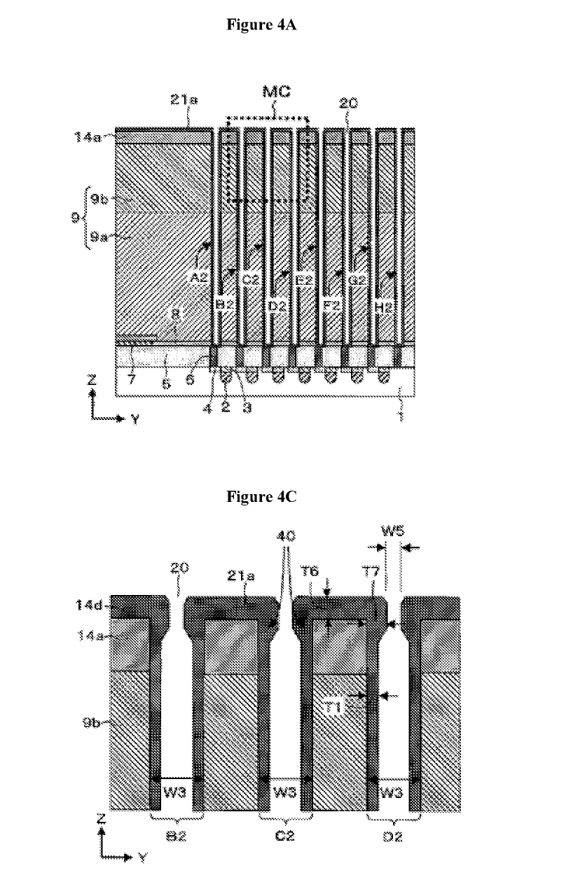

Next, as illustrated in FIG. 4A, the step of forming the lower electrode material film is carried out. A lower electrode material film 21a is formed over the entire surface of the semiconductor substrate 1, including the inner surfaces of the cylinder holes 20. A titanium nitride (TiN) film can be used as the material for the lower electrode material film 21a. Further, CVD, ALD (Atomic Layer Deposition) or the like can be used to form the lower electrode material film 15. The lower electrode material film 21a formed in the cylinder holes 20 is formed in such a way that its thickness T1 in a location in close proximity to the insulating film 14a is 10 nm, for example.

However, as illustrated in FIG. 4C, when the lower electrode material film 21a having the thickness T1 necessary to maintain the characteristics of the capacitor inside the cylinder hole 20 located below the insulating film 14a is formed, a widened portion 40 that is widened in the Y-direction and has a thickness T7 approximately twice the thickness T1 is formed on the upper end portion of the side surface of the insulating film 14a. This is a phenomenon that inevitably occurs as a result of the fact that when the diameter of the cylinder hole 20 is reduced, there is an insufficient supply of deposition gas molecules into cylinder hole 20, and the deposition speed is reduced, but in the upper end portion, where there is a sufficiency of deposition gas molecules, the deposition speed does not reduce. Thus if the lower electrode material film 21a is formed in such a way that its thickness T1 is 10 nm, the film thickness T7 at the upper end portion of the side surface of the insulating film 14a is 18 nm. The film thickness T6 at the upper surface 14d of the insulating film 14a is thicker still, being 25 nm. To put this another way, in order to form the lower electrode material film 21a to a thickness of 10 nm inside the cylinder hole 20, a lower electrode material film having a thickness of 25 nm must be formed at the upper surface 14d of the insulating film 14a. In this mode of embodiment, the diameter L0 of the hole in the uppermost layer is 50 nm, and therefore the diameter W5 of the opening portion of the cylinder hole 20 is reduced to 14 nm. Therefore, if the capacitative insulating film is formed in this state, the opening portion of the cylinder hole 20 will be occluded.

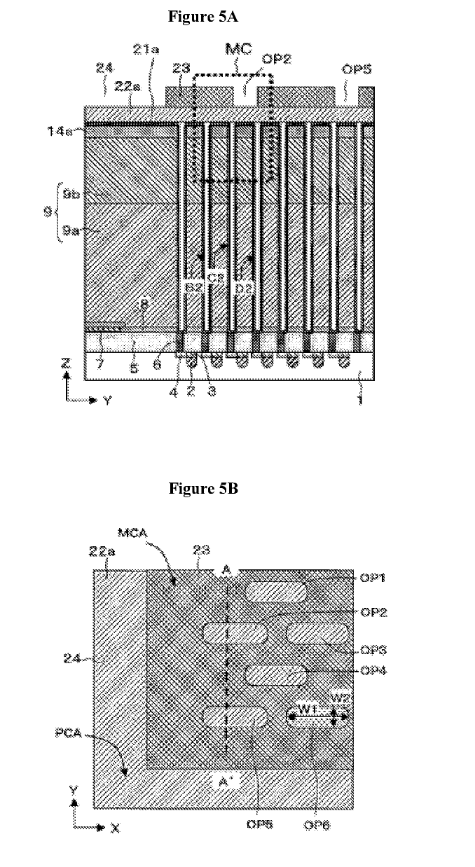

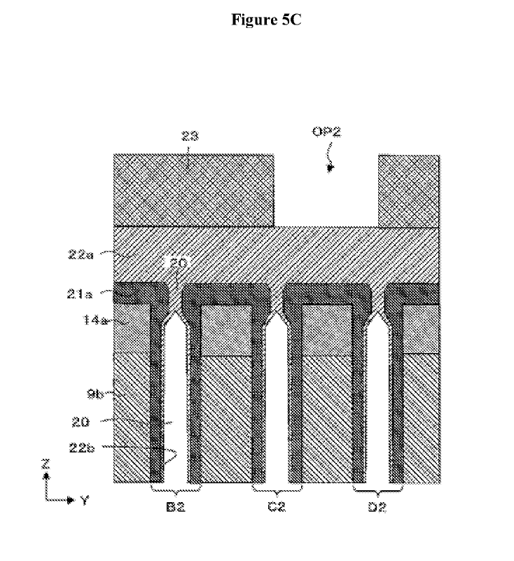

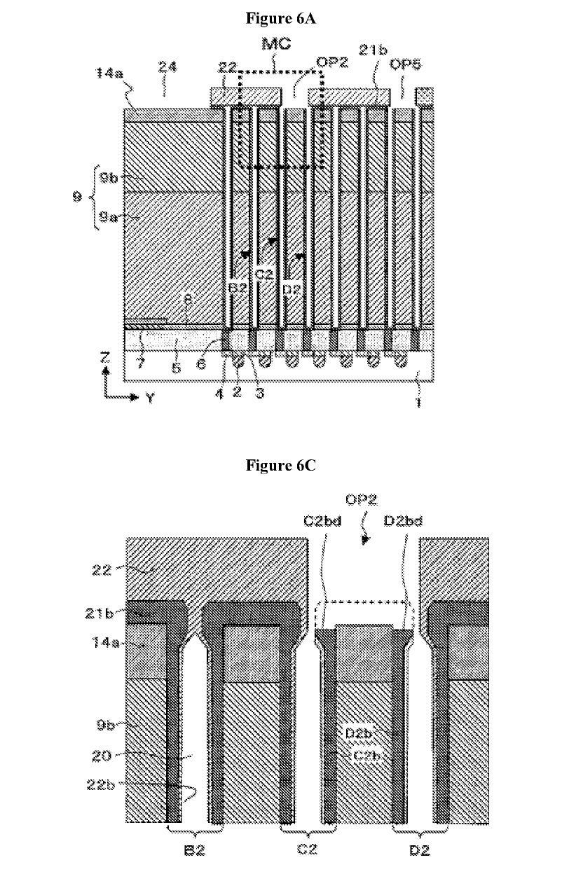

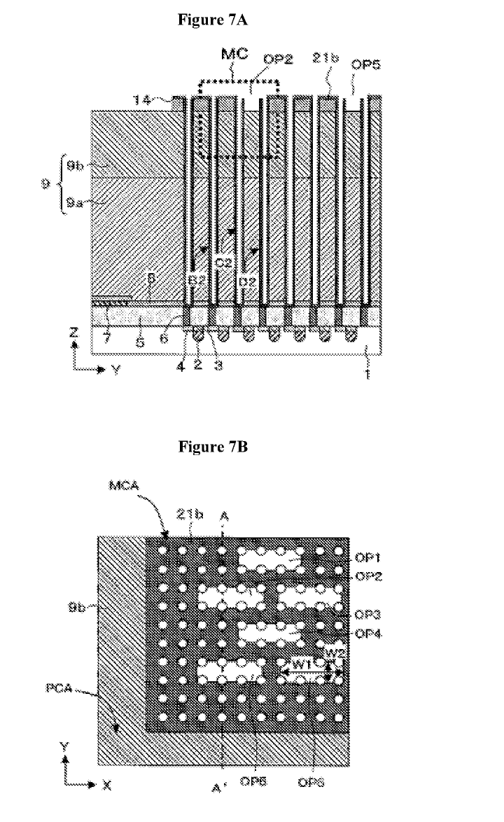

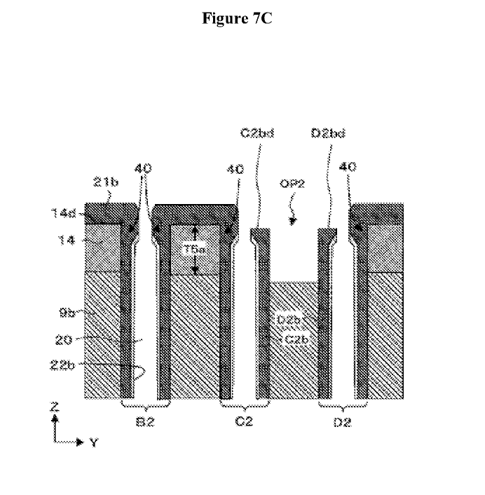

The steps to form the support film 14 are next carried out, as illustrated in FIG. 5A, FIG. 5B, FIG. 5C, FIG. 6A, FIG. 6C, FIG. 7A, FIG. 7B and FIG. 7C. First, as illustrated in FIG. 5A, a protective film 22a comprising a silicon dioxide film is formed over the entire surface by plasma CVD. The thickness of the protective film 22a is, for example, 100 nm, on the lower electrode material film 21a. The protective film 22a formed by plasma CVD has poor coverage, and therefore, as illustrated in FIG. 5C, it does not readily form inside the cylinder holes 20, but a protective film 22b having a thickness of approximately 4 nm is formed. By this means the upper end portions of the cylinder holes 20 are occluded by the protective film 22a. The protective film 22a is formed in order to prevent a masking film comprising a photoresist from forming inside the cylinder holes 20 in a lithography step carried out in a subsequent step. The reason for this is that if the cylinder holes, which have a high aspect ratio, are filled with an organic substance, it is difficult to remove said organic substance. Further, the protective film 22b has the role of protecting the lower electrodes formed in the cylinder holes 20 in a subsequent step from being etched.

A masking film 23 having a pattern of openings formed by a second lithography step is next formed on the protective film 22a. As illustrated in FIG. 5B, a peripheral opening 24 is formed in the peripheral circuit region PCA, and the masking film 23 is formed in such a way as to cover the memory cell region MCA. Six first openings OP1 to OP6, for example, are formed in the masking film 23. As described in FIG. 1B, each opening has a width W1 in the X-direction and a width W2 in the Y-direction. Further, each opening has a pattern configuration whereby a first unit cylinder hole group corresponding to a first unit lower electrode group comprising four lower electrodes that are adjacent in the X-direction, and a second unit cylinder hole group corresponding to a second unit lower electrode group comprising four lower electrodes that are adjacent and are aligned in the Y-direction are exposed collectively. In other words, each opening is formed in such a way as to straddle eight cylinder holes 20.

FIG. 5C is an enlarged cross-sectional view of the region MC illustrated in FIG. 5A. The masking film 23 is formed in such a way that the side surfaces of the opening OP2 are located in the central portions, in the Y-direction, of the cylinder holes corresponding to the lower electrodes C2 and D2.

Next, as illustrated in FIG. 6A and FIG. 6C, the protective film 22a exposed in the peripheral opening 24 and the openings OP1 to OP6 is removed by anisotropic dry etching employing fluorine-containing plasma, using the masking film 23 as a mask. By this means, the upper surface of the lower electrode material film 21a is exposed in the peripheral opening 24 and the openings OP2 and OP5. The masking film 23 is then removed. The lower electrode material film 21a, the upper surface of which has been exposed, is then removed by anisotropic dry etching using a mixed-gas plasma containing chlorine (Cl₂) and boron trichloride (BCl₃). By this means the upper surface of the insulating film 14a in the peripheral opening 24 and the openings OP2 and OP5 is exposed. Further, an upper surface C2bd of the second part C2b of the lower electrode C2, and the upper surface D2bd of the second part D2b of the lower electrode D2, located on the side surfaces of the exposed insulating film 14a, are exposed. It should be noted that the surfaces of the lower electrodes C2b and D2b formed within the cylinder holes 20 are protected by the protective film 22b, and are not etched. At this stage the protective film 22a and the lower electrode material film 21a become the protective film 22 and the lower electrode material film 21b onto which the pattern of openings has been transferred. The state is such that the lower electrode material film 21b remains on the insulating film 14a in regions other than the openings OP1 to OP6.

Next, as illustrated in FIG. 7A, 7B and 7C, the insulating film 14a, the upper surface of which is exposed in the peripheral opening and the first openings OP1 to OP6, is removed by anisotropic dry etching employing a mixed-gas plasma containing tetrafluorocarbon (CF₄) and trifluoromethane (CHF₃), using the protective film 22 as a mask. By means of this etching, the protective film 22 formed on the lower electrode material film 21b is also etched and eliminated. However, the protective film 22b formed within the cylinder holes 20 is not etched, and remains. By this means, the support film 14 comprising the insulating film 14a is formed. The state is such that the upper surface of the lower electrode material film 21b is exposed above the support film 14. Further, the upper surface of the second sacrificial film 9b is exposed in the peripheral opening and the openings. The second part C2b of the lower electrode C2, having the upper end C2bd, and the second part D2b of the lower electrode D2, having the upper end D2bd, are formed in such a way as to protrude from the upper surface of the second sacrificial film 9b. At this stage, the locations of the upper ends C2bd and D2bd are equivalent to the location of the upper surface 14d of the support film 14. In this anisotropic dry etching, after the upper surface of the lower electrode material film 21b on the support film 14 has been exposed, a step is additionally carried out in which the second sacrificial film 9b, the upper surface of which is exposed within the opening, is etched back 10 nm, using the lower electrode material film 21b as a mask.

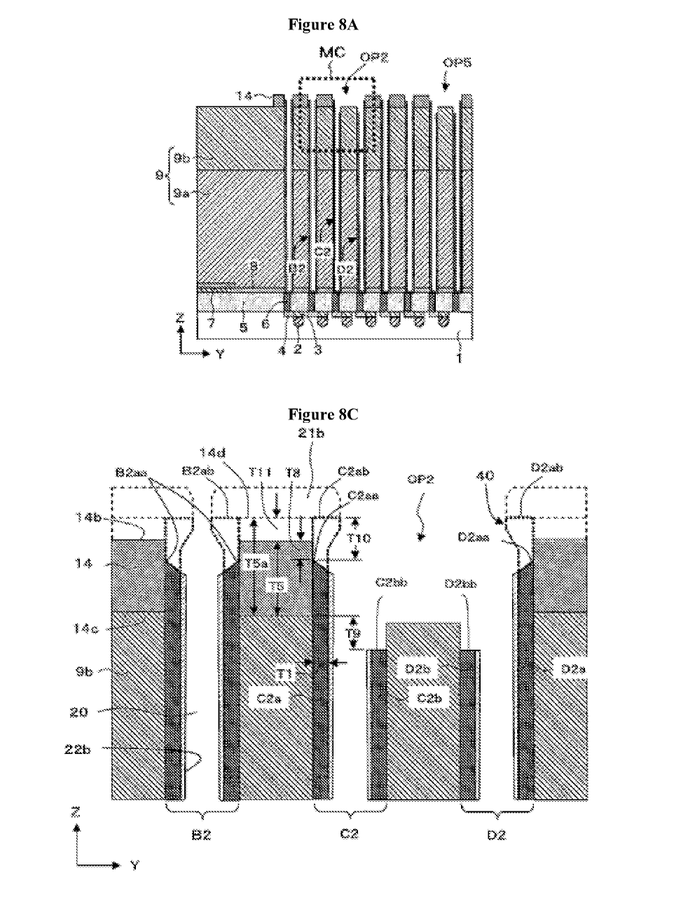

Next, as illustrated in FIG. 8A and FIG. 8C, a step is carried out to remove the widened portion 40 of the lower electrode material film 21b which, at the stage in FIG. 7, has been formed on the upper end portions of the side surfaces of the support film 14. The lower electrode material film 21b formed on the support film 14 is successively etched from its upper surface by anisotropic dry etching employing a mixed-gas plasma containing chlorine (Cl₂), nitrogen (N₂) and argon (Ar). The following conditions can be given by way of example for this etching. A capacitively coupled type of plasma etching device can be used as the device, but preferably an inductively coupled type of plasma etching device is used. The gas supply ratio is N₂:Cl₂:A4=1:1.5 to 2.5:3 to 4. As a preferred ratio, the ratio can be 1:1.8:3.3. The pressure is 0.13 to 1.3 (Pa), preferably 0.8 (Pa). The high-frequency power is 600 to 1000 (W), preferably 800 (W). The high-frequency bias power is 300 to 500 (W), preferably 400 (W). The semiconductor substrate temperature is 20 to 25° C.

First, using the abovementioned etching conditions, a first etching step is implemented, in which the lower electrode material film 21b formed above the upper surface 14d of the support film 14 is removed to expose the upper surface 14d of the support film 14, and to expose the upper surfaces B2ab and C2ab of the widened portions 40 formed on the side surfaces of the support film 14. At this stage, the upper surfaces B2ab and C2ab are coplanar with the upper surface 14d of the support film 14. A second etching step, which is a continuation of the first etching step, is then carried out to etch simultaneously the silicon nitride film forming the support film 14 and the titanium nitride film forming the lower electrode material film 21b, etching being performed until the difference T8 in the Z-direction between the new upper surface 14b of the support film 14 and upper ends B2aa, C2aa and D2aa of the titanium nitride film is between 20 and 50% of the thickness T5 of the remaining support film 14. In other words, etching is performed until the upper ends of the lower electrodes B2, C2a and D2a are in locations that are between 20 and 50% of the thickness T5 lower than the upper surface 14b of the support film 14.

With anisotropic dry etching employing the abovementioned conditions, the silicon nitride film and the titanium nitride film are etched simultaneously, but the conditions are such that the etching rate of the titanium nitride film is faster than the etching rate of the silicon nitride film. For example, the etching rate of the titanium nitride film can be adjusted within a range of 5 to 7 (nm/sec), and the etching rate of the silicon nitride film can be adjusted within a range of 2 to 4 (nm/sec). In other words, the etching rate of the titanium nitride film can be set to within a range of 1.25 to 3.5 times the etching rate of the silicon nitride film. Here, the etching rate of the titanium nitride film is set to 6 (nm/sec), and the etching rate of the silicon nitride film is set to 3.5 (nm/sec). Therefore a difference T8 between the upper surface 14b of the support film 14 and the upper ends of the lower electrodes B2, C2a and D2a, which are coplanar when etching begins in the second etching step, increases as the etching progresses.

As illustrated in FIG. 8C, the upper surfaces B2ab, C2ab and D2ab of the lower electrodes B2, C2a and D2a become inclined surfaces as a result of the etching in the second etching step, and are etched to form new upper ends B2aa, C2aa and D2aa, as illustrated in FIG. 8C. The etching depth T10 from the original upper surfaces to the new upper ends is 70 nm. At this time, the upper surface 14d of the support film 14 is etched as far as a new upper surface 14b, and the etching depth T11 thereof is 40 nm. By this means, the thickness T5a of the support film 14, which was 140 nm at the stage in FIG. 7, is reduced to a new thickness T5 of 100 nm at the stage in FIG. 8. Further, the depth T8 of the upper ends B2aa, C2aa and D2aa from the upper surface 14b is 30 nm. Therefore, in the lower electrodes C2 and D2 of the first capacitors, a portion of the upper end of which is located within the opening OP2, the upper ends C2aa and D2aa of the first part, the upper end of which is not located within the opening OP2, is formed in a location that is lower than the upper surface 14b of the support film 14 by a distance corresponding to 30% of the thickness T5 of the support film 14. Further, the upper end of the lower electrode B2 of the second capacitor, the upper end of which is not located within the opening, is formed in the same way. As illustrated in FIG. 8C, the upper surfaces of the lower electrodes in this mode of embodiment are formed as inclined surfaces, and it is therefore possible to suppress problems whereby an electric field concentrates in the capacitative insulating film formed on the lower electrode, thereby increasing the leakage current, as a result of the upper end of the lower electrode having sharp corners.

Meanwhile, in the lower electrodes C2 and D2 of the first capacitors, the upper ends of which are exposed by the etching in the first etching step and the second etching step, the upper ends C2bb and D2bb of the second parts, the upper ends of which are located in the opening OP2, are formed in such a way that the depth T9 at which they are located below the lower surface 14c of the support film 14 is 20 to 50 nm. In other words, they are located lower than the lower surface 14c by a distance corresponding to 20 to 50% of the thickness T5 of the support film 14.

In the anisotropic dry etching described in FIG. 8C, etching progresses mainly in the Z-direction, but because there is a slight isotropy, etching also proceeds in the X-direction and the Y-direction, although at a low etching rate. The thickness T1 of the lower electrodes formed in the cylinder holes 20 is very small, being 10 nm, and therefore if they are etched even slightly, there is a risk that they will not function as lower electrodes. In other words, if the thickness of the lower electrodes comprising titanium nitride is reduced to less than 5 nm, a problem arises in that they do not function as electrodes. However, in this mode of embodiment the surfaces of the lower electrodes 21b formed in the cylinder holes 20 are covered by the protective film 22b, and therefore a reduction in the thickness of the lower electrodes 21b can be avoided. It should be noted that etching to round the upper surfaces of the lower electrodes may be performed following the anisotropic dry etching in FIG. 8, employing a mixed-gas plasma containing BCl₃ and argon. By this means, unevenness in the upper surfaces of the lower electrodes can be reduced, and leakage currents in the capacitative insulating film resulting from electric field concentrations can be suppressed further.

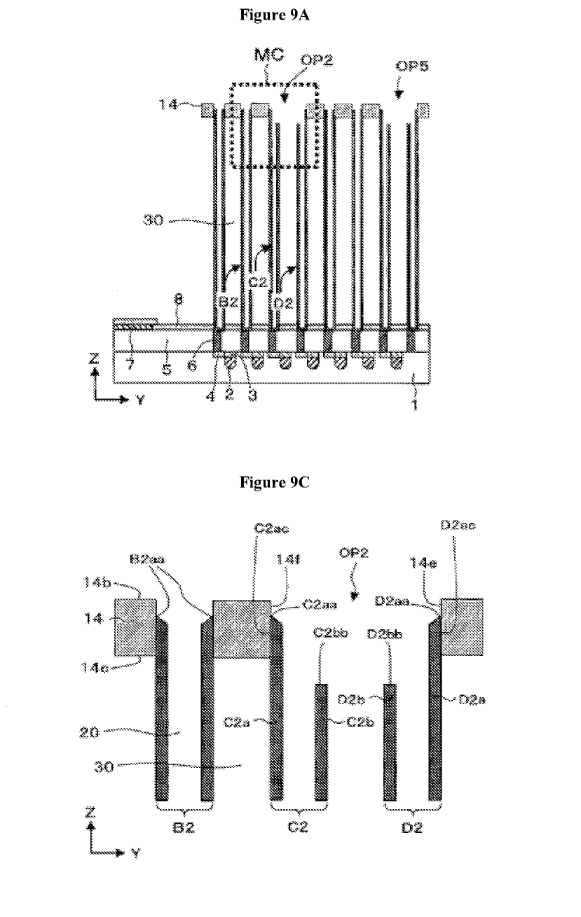

A step to remove the sacrificial films is then carried out, as illustrated in FIG. 9A and FIG. 9C. The second sacrificial film 9b comprising a non-doped silicon dioxide film, and the first sacrificial film 9a comprising a BPSG film are completely removed via the peripheral opening and the openings OP2 and OP5 by wet etching employing a hydrofluoric acid-containing solution. Further, in the step of removing the sacrificial films, the protective film 22b discussed hereinabove is also removed. By this means, the lower surface 14c of the support film 14 and the upper surface of the stopper silicon nitride film 8 are exposed. The upper end portions C2ac and D2ac of the outer peripheral side surfaces of the first parts C2a and D2a of the first lower electrodes C2 and D2 which form the first capacitors are respectively connected to the side surfaces 14f and 14e of the support film 14. Further, the upper end portion of the outer peripheral side surface of the lower electrode B2 which forms the second capacitor is also configured in the same way. Therefore, each of the lower electrodes is connected to the side surface of the support film, and therefore the lower electrodes do not collapse even when the sacrificial film 9 has been removed. Further, a continuous void 30 forms at the periphery of all the lower electrodes, below the support film 14. As illustrated in FIG. 9C, the state is such that the upper surface 14b and the lower surface 14c of the support film 14, and the inner surfaces and the outer peripheral side surfaces of the lower electrodes are all exposed.

Next, as illustrated in FIG. 1A and FIG. 1C, steps are carried out to form a capacitative insulating film and an upper electrode. A capacitative insulating film 25 is formed by ALD over the entire surface, including the upper surface 14b and the lower surface 14c of the support film 14, the upper surface of the stopper silicon nitride film 8, and the inner and outer surfaces of the lower electrodes. The capacitative insulating film 25 can be formed with zirconium oxide as its main component. The capacitative insulating film 25 is formed to a thickness of 7 nm, and therefore the upper-end opening portions of the cylinder holes 20 are not occluded, as illustrated in FIG. 1C. As discussed hereinabove, the width W6 of the opening portions of the lower electrodes prior to formation of the capacitative insulating film 25 is 30 nm, and therefore, even at the stage at which the capacitative insulating film 25 has been formed, upper-end openings having a width of 16 nm exist. Therefore an upper electrode 26, formed in such a way as to cover the capacitative insulating film 25, can be formed within the cylinder holes 20 to a thickness of at least 8 nm. Capacitors can be formed by this means. Next, as illustrated in FIG. 1A, the upper electrode formed on the peripheral circuit region PCA is removed by lithography and dry etching. A second interlayer insulating film 27 is then formed over the entire surface, after which the surface is planarized. A DRAM can be manufactured by forming a via plug 28 in the second interlayer insulating film 27, and then forming an upper-layer wiring line 29.

As described hereinabove, according to the present invention, the upper ends of the second lower electrodes, which form the second capacitors that are not located within the openings formed in the support film 14, are located between the upper surface 14b and the lower surface 14c of the support film 14, with the widened portions 40 of the lower electrode material film 21b, located at the upper end portions of the side surfaces of the support film 14, having been removed, and therefore occlusion of the upper end portions of the cylinder holes 20 can be avoided, and capacitors can be formed even if the diameter of the cylinder holes is small.

### Second Embodiment

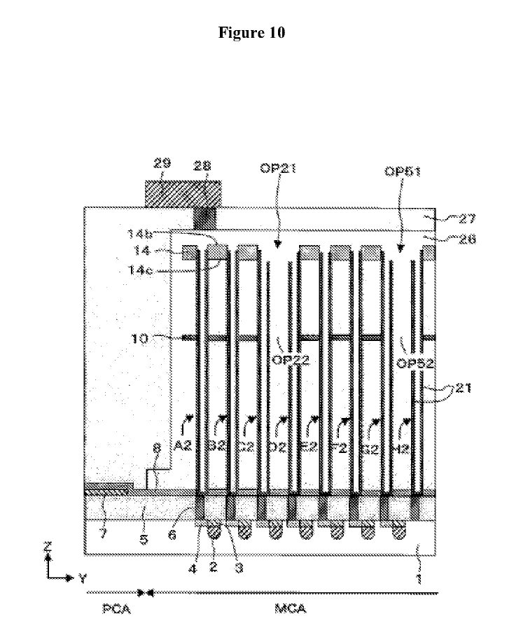

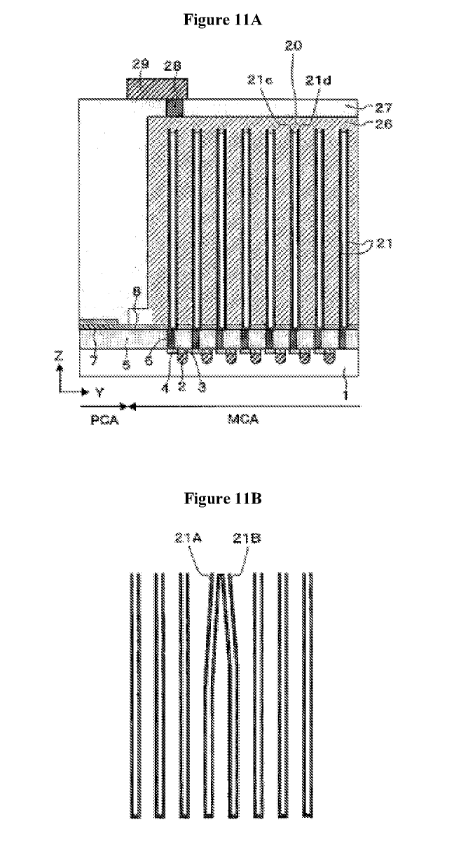

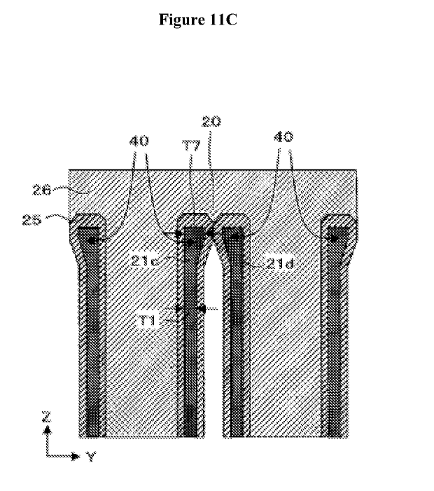

FIG. 10 is a cross-sectional view illustrating the configuration in a second mode of embodiment of the present invention. The basic configuration is the same as in FIG. 1A, and duplicate descriptions are therefore omitted. The configuration differs from the first mode of embodiment in that an intermediate support film 10 is disposed midway along the plurality of lower electrodes, in the Z-direction. The location in the Z-direction in which the intermediate support film 10 is disposed is a location that is higher than half of the height of the lower electrodes (A2, B2 and the like) forming the second capacitors described in the first mode of embodiment, and lower than ¾ of the height from the upper ends of the lower electrodes. The intermediate support film 10 has second openings OP22 and OP52 having the same layout as the openings illustrated in FIG. 1B. Further, the second openings OP22 and OP52 are disposed in locations that are aligned with and overlap first openings OP21 and OP51 in the Z-direction. According to this second mode of embodiment, occlusion of the open portions of the cylinder holes by the lower electrodes can be avoided, and the support of the lower electrodes can be enhanced, further reducing failures attributable to the lower electrodes moving together.

Preferred modes of embodiment of the present invention have been described hereinabove, but various modifications to the present invention may be made without deviating from the gist of the present invention, without limitation to the abovementioned modes of embodiment, and it goes without saying that these are also included within the scope of the present invention. For example, the Y-direction is referred to as the first direction, and the X-direction is referred to as the second direction, but there is no difference if the directions are interchanged.

### EXPLANATION OF THE REFERENCE NUMBERS

1 Semiconductor substrate

2 Embedded gate electrode

3 Cap insulating film

4 Impurity-diffused layer

5 First interlayer insulating film

6 Contact plug

7 Peripheral circuit

8 Stopper silicon nitride film

9a First sacrificial film

9b Second sacrificial film

10 Intermediate support film

14 Support film

14a Insulating film

14b Upper surface after etch-back of support film

14c Lower surface of support film

14d Upper surface of support film before etch-back

15 Hardmask film

15a Amorphous silicon film

15b Silicon dioxide film

15c Amorphous carbon film

18 Organic masking film

19 Cylinder hole pattern

20 Cylinder hole

21a, 21b Lower electrode material film

21 Lower electrode

22, 22a, 22b Protective film

23 Masking film

24 Peripheral opening

OP1 to OP6 Opening

A2 to H2 Lower electrode

C2a, C2b Lower electrode

B2aa, C2aa, D2aa, C2bb, D2bb Upper end of lower electrode

C2a, C2b, D2a, D2b Lower electrode

25 Capacitative insulating film

26 Upper electrode

27 Second interlayer insulating film

28 Via plug

29 Upper-layer wiring line

30 Void

40 Widened portion of lower electrode

1. A semiconductor device comprising:
a plurality of lower electrodes extending in a third direction perpendicular to a semiconductor substrate surface;
a support film which is located in a plate-like manner, connected to an upper end portion of an outer peripheral side surface of each lower electrode, and which has an opening encompassing a plurality of the lower electrodes;
a capacitative insulating film covering the surfaces of the lower electrodes; and
an upper electrode covering the surface of the capacitative insulating film, wherein the plurality of capacitors include first capacitors provided with first lower electrodes in which a portion of the upper end of the lower electrode is located within the opening as seen in a plan view, and second capacitors provided with second lower electrodes in which the upper end of the lower electrode is not located within the opening, and wherein the first lower electrodes are formed from a first part which is not located within the opening, and a second part which is located within the opening, and the upper end of the first part is located between the upper surface of the support film and the lower surface of the support film, the upper end of the second part is located lower than the lower surface of the support film, and the upper end of the second lower electrode is located between the upper surface of the support film and the lower surface of the support film.

2. The semiconductor device of claim 1, wherein the upper end of the first part and the upper end of the second lower electrode are each located lower than the upper surface of the support film by a distance corresponding to between 20 and 50% of the thickness of the support film.

3. The semiconductor device of claim 1, wherein the upper end of the second part is located lower than the lower surface of the support film by a distance corresponding to between 15 and 70% of the thickness of the support film.

4. The semiconductor device of claim 1, wherein the opening is formed from a rectangle comprising short edges extending in a first direction and long edges extending in a second direction perpendicular to the first direction, two first capacitors opposing one another in the first direction are provided within the opening, and the first lower electrodes which form each of the first capacitors comprise the first part, the upper end of which is not located in the opening, and the second part, the upper end of which is located in the opening, and the respective second parts having an upper end located lower than the lower surface of the support film oppose one another in closest proximity to one another.

5. The semiconductor device of claim 1, wherein the lower electrodes are disposed aligned in straight lines in the first direction and the second direction, have a ring shape as seen in a plan view, and have an arrangement pitch defined as the sum of the diameter of the lower electrode and the gap between two adjacent lower electrodes, and the opening comprises long edges extending a distance three times the arrangement pitch in the second direction, and short edges extending a distance equal to the arrangement pitch in the first direction.

6. The semiconductor device of claim 1, wherein four lower electrodes adjacent in the second direction, from the plurality of lower electrodes adjacent to one another in the first direction and the second direction, serve as a unit lower electrode group, and the opening is formed in such a way as to expose collectively portions of the respective upper ends of two adjacent unit lower electrode groups aligned in the first direction.

7. The semiconductor device of claim 1, wherein the opening is disposed straddling the upper ends of four lower electrodes that overlap the corner portions of said opening, and the upper ends of four lower electrodes that overlap the long edges of said opening.

8. The semiconductor device of claim 1, wherein openings that are adjacent to one another in the second direction are disposed in a straight line, and the gap between two adjacent holes comprises the arrangement pitch.

9. The semiconductor device of claim 1, wherein the gap between adjacent openings in the first direction is the arrangement pitch, and said openings are disposed in a staggered manner in locations that are offset by twice the arrangement pitch in the second direction.

10. The semiconductor device of claim 1, wherein the centerlines of the openings in the second direction do not intersect other openings that are in closest adjacent proximity in the first direction.

11. The semiconductor device of claim 1, wherein, of a plurality of the openings disposed in the first direction, alternate openings are disposed in a straight line.

12. The semiconductor device of claim 1, comprising a memory cell region and a peripheral circuit region, and the beam is formed from a continuous face connected to all the lower electrodes located within one memory cell region.

13. A semiconductor device comprising:
a support film which is disposed above a semiconductor substrate and has a first side surface and a second side surface facing the first side surface in a first direction parallel to the surface of the semiconductor substrate;
a second capacitor having a second lower electrode which is in contact with the first side surface of the support film and an upper end of which is disposed between an upper surface and a lower surface of the support film; and
a first capacitor having a first lower electrode formed from a first part which is in contact with the second side surface of the support film and an upper end of which is disposed between the upper surface and the lower surface of the support film, and a second part which is not in contact with the support film and an upper end of which is located lower than the lower surface of the support film.

14. A semiconductor device comprising:
a support film which is disposed above a semiconductor substrate and has a first side surface and a second side surface facing the first side surface in a first direction parallel to the surface of the semiconductor substrate;
a first capacitor having a first lower electrode formed from a first part which is in contact with the first side surface of the support film and an upper end of which is disposed between the upper surface and the lower surface of the support film, and a second part which is not in contact with the support film and an upper end of which is located lower than the lower surface of the support film; and
another first capacitor having a first lower electrode formed from a first part which is in contact with the second side surface of the support film and an upper end of which is disposed between the upper surface and the lower surface of the support film, and a second part which is not in contact with the support film and an upper end of which is located lower than the lower surface of the support film;
wherein the first capacitor, the other first capacitor, and the support film located between the first capacitor and the other first capacitor serve as a unit configuration, and the semiconductor device includes a configuration in which the unit configuration is disposed in a repeating manner in the second direction.
